(19) United States
(12) Patent Application Publication
(10) Pub. No.: US 2022/0403529 A1
(43) Pub. Date: Dec. 22, 2022

(54) Manufacturing Method of Nitride Semiconductor Photoelectrode

(71) Applicant: Nippon Telegraph and Telephone Corporation, Tokyo (JP)

(72) Inventors: Yuya Uzumaki, Musashino-shi, Tokyo (JP); Sayumi Sato, Musashino-shi, Tokyo (JP); Yoko Ono, Musashino-shi, Tokyo (JP); Takeshi Komatsu, Musashino-shi, Tokyo (JP)

(21) Appl. No.: 17/780,277

(22) PCT Filed: Dec. 3, 2019
(86) PCT No.: PCT/JP2019/047157

§ 371 Date: May 26, 2022

(51) Int. Cl. C23C 28/04; C23C 16/34; C23C 16/56; C23C 14/58; C25B 11/053

(52) U.S. Cl. CPC C23C 28/04; C23C 16/34; C23C 16/56; C23C 14/5806; C25B 11/053; C25B 1/04

(57) ABSTRACT

A method for producing a nitride semiconductor photoelectrode includes: a first step of forming an n-type gallium nitride layer on an electrically insulative or conductive substrate; a second step of forming an indium gallium nitride layer on the n-type gallium nitride layer; a third step of forming a p-type nickel oxide layer on the indium gallium nitride layer; and a fourth step of subjecting a nitride semiconductor in which the p-type nickel oxide layer has been formed to heat treatment.

### TECHNICAL FIELD

The present invention relates to a method for producing a nitride semiconductor photoelectrode.

### BACKGROUND ART

Water decomposition devices using semiconductor photoelectrodes have an oxidation tank and a reduction tank connected via a proton exchange membrane, and an aqueous solution and an oxidation electrode are placed in the oxidation tank and an aqueous solution and a reduction electrode are placed in the reduction tank. The oxidation electrode and the reduction electrode are electrically connected by a conductive wire. For example, a gallium nitride thin film grown on a sapphire substrate is used as the oxidation electrode.

The decomposition reaction of water using a photocatalyst consists of the oxidation reaction of water and the reduction reaction of protons. When the oxidation electrode is irradiated with light, electrons and holes are generated and separated in the photocatalyst. The holes are transferred to the surface of the photocatalytic material and contribute to the oxidation reaction of water. On the other hand, electrons are transferred to the reduction electrode and contribute to the reduction reaction of protons. Ideally, such an oxidation-reduction reaction would proceed, resulting in the decomposition reaction of water.

Oxidation reaction: 2H₂O+4h⁺→O₂+4H⁺

Reduction reaction: 4H⁺+4e⁻→2H₂

In the gallium nitride thin film, holes generated and separated under the light irradiation are consumed in the etching reaction of gallium nitride itself at the same time as the oxidation reaction of water. This causes a problem that the photoelectrode is degraded and the light energy conversion efficiency is decreased along with the light irradiation time.

In order to suppress such degradation, Non-Patent Literature 2 reports an example where a co-catalyst (nickel oxide) for oxygen generation is formed as a protective layer to improve the service life.

### CITATION LIST

### Non-Patent Literature

Non-Patent Literature 1: S. Yotsuhashi, et al., “CO2 Conversion with Light and Water by GaN Photoelectrode”, Japanese Journal of Applied Physics, The Japan Society of Applied Physics, 2012, Volume 51, pp. 02BP07-1-02BP07-3
Non-Patent Literature 2: Yoko Ono, Yuya Uzumaki, Kazuhide Kumakura, and Takeshi Komatsu, “Effects of NiO Thin Film Formed on Nitride Semiconductor Electrode on Photocurrent Characteristics”, ECSJ Fall Meeting, 2017, The Electrochemical Society of Japan, 1L31

### SUMMARY OF THE INVENTION

### Technical Problem

The holes generated in the gallium nitride thin film used as the oxidation electrode are transferred from the gallium nitride thin film to nickel oxide, and the oxidation reaction of water proceeds on the surface of nickel oxide. In order for the holes to be transferred smoothly, the valence band of the gallium nitride semiconductor is required to be at a lower level than the valence band of nickel oxide.

However, in the case of visible light-responsive semiconductor photocatalyst thin films, such as indium gallium nitride, which are expected to improve the light absorptance, the valence band level becomes higher as the band gap becomes narrower. The valence band of nickel oxide fabricated by conventional approaches is located at a lower level than the valence band of visible light-responsive semiconductor photocatalyst thin films, creating a barrier that prevents holes from being transferred. Therefore, even if the light absorptance is improved, holes cannot be transferred due to the created barrier, and there is a problem that the nickel oxide does not function as the co-catalyst protective layer.

The present invention has been made in view of the above, and an object of the present invention is to provide a nitride semiconductor photoelectrode that can maintain the light energy conversion efficiency at a high level for a long time.

### Means for Solving the Problem

One aspect of the present invention provides a method for producing a nitride semiconductor photoelectrode, the method comprising: a first step of forming an n-type gallium nitride layer on an electrically insulative or conductive substrate; a second step of forming an indium gallium nitride layer on the n-type gallium nitride layer; a third step of forming a p-type nickel oxide layer on the indium gallium nitride layer; and a fourth step of subjecting the p-type nickel oxide layer to heat treatment.

### Effects of the Invention

According to the present invention, a nitride semiconductor photoelectrode that can maintain the light energy conversion efficiency at a high level for a long time can be provided.

### BRIEF DESCRIPTION OF DRAWINGS

FIG. 1 is a cross-sectional view illustrating the configuration of a nitride semiconductor photoelectrode fabricated by the method for producing a nitride semiconductor photoelectrode of the present embodiment.

FIG. 2 is a flow chart showing the method for producing a nitride semiconductor photoelectrode of the present embodiment.

FIG. 3 illustrates the outline of a device for carrying out an oxidation-reduction reaction test.

### DESCRIPTION OF EMBODIMENTS

Hereinafter, an embodiment of the present invention will be described with reference to the accompanying drawings. Note that the present invention is not limited to the embodiment described below, and modifications may be made within the scope that they do not depart from the spirit of the present invention.

### Configuration of Nitride Semiconductor Photoelectrode

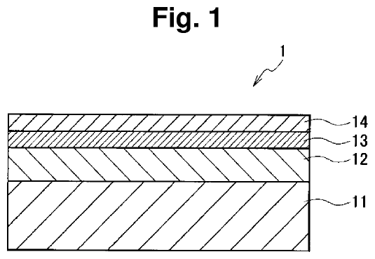

FIG. 1 is a cross-sectional view illustrating the configuration of a nitride semiconductor photoelectrode fabricated by the method for producing a nitride semiconductor photoelectrode of the present embodiment.

A nitride semiconductor photoelectrode 1 illustrated in FIG. 1 comprises an electrically insulative or conductive substrate (sapphire substrate) 11, an n-type gallium nitride (n-GaN) layer 12 arranged on the substrate 11, an indium gallium nitride (InGaN) layer 13 arranged on the n-type gallium nitride layer 12, and a p-type nickel oxide (p-NiO) layer 14 arranged on the indium gallium nitride layer 13.

When nickel oxide, which is a co-catalyst for oxygen generation, is doped with lithium as an impurity, it exhibits characteristics as a p-type semiconductor. Using this, by producing the nitride semiconductor photoelectrode 1 in which the p-type nickel oxide layer 14 has been formed on the indium gallium nitride layer 13, holes generated in the indium gallium nitride layer 13 by light irradiation can be transferred to the p-type nickel oxide layer 14.

### Method for Producing Nitride Semiconductor Photoelectrode

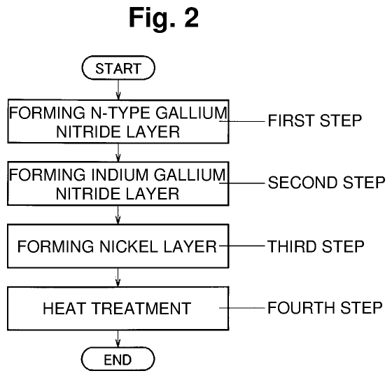

The method for producing a nitride semiconductor photoelectrode of the present embodiment will be described with reference to FIG. 2.

In a first step, an n-type gallium nitride layer 12 is formed on an electrically insulative or conductive substrate 11. The n-type gallium nitride layer 12 may be formed by using metal organic chemical vapor deposition (MOCVD).

In a second step, an indium gallium nitride layer 13 is formed on the n-type gallium nitride layer 12. The indium gallium nitride layer 13 may be formed by using MOCVD.

In a third step, a p-type nickel oxide layer 14 is formed on the indium gallium nitride layer 13. The p-type nickel oxide layer 14 may be formed by using vapor deposition or sputtering.

In a fourth step, a nitride semiconductor in which the p-type nickel oxide layer 14 has been formed is subjected to heat treatment. The heat treatment is preferably performed at a temperature of 200° C. or higher and 800° C. or lower.

Hereinafter, Examples 1 to 18 will be described, in which the nitride semiconductor photoelectrode 1 was fabricated changing the heat treatment temperature in the fourth step and the composition ratio of lithium when fabricating p-NiO used to form the p-type nickel oxide layer 14 in the third step. Examples 1 to 5 are working examples of the method for producing a nitride semiconductor photoelectrode at different heat treatment temperatures. Examples 6 to 10 and Examples 11 to 15 are working examples where nitride semiconductor photoelectrodes were fabricated at the heat treatment temperatures of Examples 1 to 5, changing the composition ratio of lithium. Example 16 is a working example of the method for producing a nitride semiconductor photoelectrode in which the composition ratio of lithium in Example 1 was changed. Examples 17 and 18 are working examples of the method for producing a nitride semiconductor photoelectrode in which the method for forming the p-type nickel oxide layer 14 in Examples 1 and 3 was changed.

### Example 1

In the first step, a silicon doped n-GaN semiconductor thin film was epitaxially grown by MOCVD on a 2-inch sapphire substrate to form an n-type gallium nitride layer 12. Ammonia gas and trimethylgallium were used as the growth raw materials. Silane gas was used as the n-type impurity source. Hydrogen was used as the carrier gas to be sent into the growth furnace. The film thickness of the n-type gallium nitride layer 12 was set to 2 μm, which is sufficient to absorb light. The carrier density was 3×10¹⁸ cm⁻³.

In the second step, an indium gallium nitride layer 13 with an indium composition ratio of 5% was grown by MOCVD on the n-type gallium nitride layer 12 to form an indium gallium nitride layer 13. Ammonia gas, trimethylgallium, and trimethylindium were used as the growth raw materials. Hydrogen was used as the carrier gas to be sent into the growth furnace. The film thickness of the indium gallium nitride layer 13 was set to 100 nm, which is sufficient to absorb light.

The sample with the n-type gallium nitride layer 12 and the indium gallium nitride layer 13 formed on the substrate 11 was cleaved into four equal pieces, one of which was used for electrode fabrication.

The p-NiO used to form a p-type nickel oxide layer 14 is fabricated by the following step. The weights of NiO powder and lithium oxide powder are determined such that the composition ratio of Li becomes the desired value, and then the NiO powder and lithium oxide powder are mixed and subjected to heat treatment in an electric furnace. In Example 1, the weights of NiO powder and lithium oxide powder were determined such that the composition ratio of Li was 1% (composition ratio of Ni was 99%). The volume resistivity of the obtained p-NiO powder was about four orders of magnitude lower than that of NiO powder, indicating that the NiO powder was converted to p-type and its electrical conductivity was improved.

In the third step, p-NiO with a film thickness of about 1 nm was deposited by electron beam (EB) on the surface of the indium gallium nitride layer 13 to form a p-type nickel oxide layer 14.

In the fourth step, the semiconductor thin film obtained up to the third step was subjected to heat treatment on a hot plate at 200° C. for 1 hour in an air atmosphere. Note that the heat treatment in the fourth step may be performed in an electric furnace, and the heat treatment atmosphere may be in an oxygen atmosphere.

By the above steps, a nitride semiconductor photoelectrode of Example 1 was obtained.

### Example 2

In the method for producing a nitride semiconductor photoelectrode of Example 2, the heat treatment temperature was set to 500° C. in the heat treatment of the fourth step. Other conditions are the same as those in Example 1.

### Example 3

In the method for producing a nitride semiconductor photoelectrode of Example 3, the heat treatment temperature was set to 800° C. in the heat treatment of the fourth step. Other conditions are the same as those in Example 1.

### Example 4

In the method for producing a nitride semiconductor photoelectrode of Example 4, the heat treatment temperature was set to 100° C. in the heat treatment of the fourth step. Other conditions are the same as those in Example 1.

### Example 5

In the method for producing a nitride semiconductor photoelectrode of Example 5, the heat treatment temperature was set to 900° C. in the heat treatment of the fourth step. Other conditions are the same as those in Example 1.

### Example 6

In the method for producing a nitride semiconductor photoelectrode of Example 6, when fabricating p-NiO used in the third step, the weights of NiO powder and lithium oxide powder were determined such that the composition ratio of Li was 10% (the ratio between Li and Ni was 1:9). Other conditions are the same as those in Example 1.

### Example 7

In the method for producing a nitride semiconductor photoelectrode of Example 7, when fabricating p-NiO used in the third step, the weights of NiO powder and lithium oxide powder were determined such that the composition ratio of Li was 10% (the ratio between Li and Ni was 1:9). Other conditions are the same as those in Example 2.

### Example 8

In the method for producing a nitride semiconductor photoelectrode of Example 8, when fabricating p-NiO used in the third step, the weights of NiO powder and lithium oxide powder were determined such that the composition ratio of Li was 10% (the ratio between Li and Ni was 1:9). Other conditions are the same as those in Example 3.

### Example 9

In the method for producing a nitride semiconductor photoelectrode of Example 9, when fabricating p-NiO used in the third step, the weights of NiO powder and lithium oxide powder were determined such that the composition ratio of Li was 10% (the ratio between Li and Ni was 1:9). Other conditions are the same as those in Example 4.

### Example 10

In the method for producing a nitride semiconductor photoelectrode of Example 10, when fabricating p-NiO used in the third step, the weights of NiO powder and lithium oxide powder were determined such that the composition ratio of Li was 10% (the ratio between Li and Ni was 1:9). Other conditions are the same as those in Example 5.

### Example 11

In the method for producing a nitride semiconductor photoelectrode of Example 11, when fabricating p-NiO used in the third step, the weights of NiO powder and lithium oxide powder were determined such that the composition ratio of Li was 40% (the ratio between Li and Ni was 4:6). Other conditions are the same as those in Example 1.

### Example 12

In the method for producing a nitride semiconductor photoelectrode of Example 12, when fabricating p-NiO used in the third step, the weights of NiO powder and lithium oxide powder were determined such that the composition ratio of Li was 40% (the ratio between Li and Ni was 4:6). Other conditions are the same as those in Example 2.

### Example 13

In the method for producing a nitride semiconductor photoelectrode of Example 13, when fabricating p-NiO used in the third step, the weights of NiO powder and lithium oxide powder were determined such that the composition ratio of Li was 40% (the ratio between Li and Ni was 4:6). Other conditions are the same as those in Example 3.

### Example 14

In the method for producing a nitride semiconductor photoelectrode of Example 14, when fabricating p-NiO used in the third step, the weights of NiO powder and lithium oxide powder were determined such that the composition ratio of Li was 40% (the ratio between Li and Ni was 4:6). Other conditions are the same as those in Example 4.

### Example 15

In the method for producing a nitride semiconductor photoelectrode of Example 15, when fabricating p-NiO used in the third step, the weights of NiO powder and lithium oxide powder were determined such that the composition ratio of Li was 40% (the ratio between Li and Ni was 4:6). Other conditions are the same as those in Example 5.

### Example 16

In the method for producing a nitride semiconductor photoelectrode of Example 16, when fabricating p-NiO used in the third step, the weights of NiO powder and lithium oxide powder were determined such that the composition ratio of Li was 50% (the ratio between Li and Ni was 5:5). Other conditions are the same as those in Example 1.

### Example 17

In the method for producing a nitride semiconductor photoelectrode of Example 17, in the third step, the target (sintered body) was fabricated from p-NiO powder, and a p-type nickel oxide layer 14 was formed by sputtering. Other conditions are the same as those in Example 1.

### Example 18

In the method for producing a nitride semiconductor photoelectrode of Example 18, in the third step, the target (sintered body) was fabricated from p-NiO powder, and a p-type nickel oxide layer 14 was formed by sputtering. Other conditions are the same as those in Example 3.

### Comparative Example 1

In the method for producing a nitride semiconductor photoelectrode of Comparative Example 1, NiO was deposited instead of p-NiO in the third step. Other conditions are the same as those in Example 1.

### Comparative Example 2

In the method for producing a nitride semiconductor photoelectrode of Comparative Example 1, NiO was deposited instead of p-NiO in the third step. Other conditions are the same as those in Example 3.

### Oxidation-Reduction Reaction Test

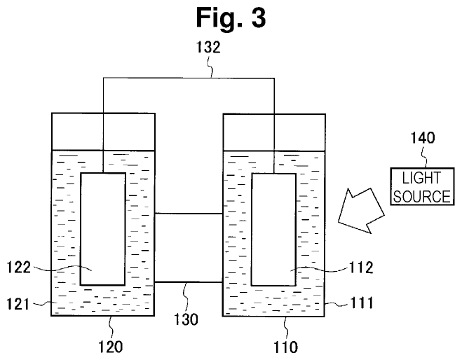

An oxidation-reduction reaction test was carried out using a device of FIG. 3 for Examples 1 to 18 and Comparative Examples 1 and 2.

The device of FIG. 3 has an oxidation tank 110 and a reduction tank 120. An aqueous solution 111 is placed in the oxidation tank 110, and an oxidation electrode 112 is placed in the aqueous solution 111. An aqueous solution 121 is placed in the reduction tank 120, and a reduction electrode 122 is placed in the aqueous solution 121.

For the aqueous solution 111 in the oxidation tank 110, a 1 mol/l aqueous sodium hydroxide solution was used. As the aqueous solution 111, an aqueous potassium hydroxide solution or hydrochloric acid may be used. When the oxidation electrode 112 is constituted by gallium nitride, an aqueous alkaline solution is preferable.

For the oxidation electrode 112, the nitride semiconductor photoelectrode to be tested was used. Specifically, the nitride semiconductor photoelectrodes of Examples 1 to 18 and Comparative Examples 1 and 2 as described above were used as the oxidation electrode 112.

For the aqueous solution 121 in the reduction tank 120, a 0.5 mol/l aqueous potassium bicarbonate solution was used. As the aqueous solution 121, an aqueous sodium bicarbonate solution, an aqueous potassium chloride solution, or an aqueous sodium chloride solution may be used.

For the reduction electrode 122, platinum (manufactured by The Nilaco Corporation) was used. The reduction electrode 122 may be a metal or a metal compound. For example, nickel, iron, gold, silver, copper, indium, or titanium may be used as the reduction electrode 122.

The oxidation tank 110 and the reduction tank 120 are connected via a proton membrane 130. The protons generated in the oxidation tank 110 are diffused via the proton membrane 130 to the reduction tank 120. For the proton membrane 130, Nafion (R) was used. Nafion is a perfluorocarbon material constituted by a hydrophobic teflon skeleton consisting of carbon-fluorine and perfluorinated side chains having sulfonic acid groups.

The oxidation electrode 112 and the reduction electrode 122 are electrically connected by a conductive wire 132, and electrons are transferred from the oxidation electrode 112 to the reduction electrode 122.

As a light source 140, a 300 W high-pressure xenon lamp (intensity of illumination: 5 mW/cm²) was used. The light source 140 may be any light source as long as it can irradiate light with a wavelength that can be absorbed by the material constituting the nitride semiconductor photoelectrode to be installed as the oxidation electrode 112. For example, in the case where the oxidation electrode 112 is constituted by gallium nitride, the wavelength that can be absorbed by the oxidation electrode 112 is a wavelength of 365 nm or less. As the light source 140, a light source such as a xenon lamp, a mercury lamp, a halogen lamp, a pseudo-sunlight source, or sunlight may be used, or these light sources may be combined.

In the oxidation-reduction reaction test, for each of Examples 1 to 18 and Comparative Examples 1 and 2, the indium gallium nitride layer 13 was scraped off to expose the n-type gallium nitride layer 12, and a conductive wire was connected to a part of the exposed surface of the n-type gallium nitride layer 12, soldered using indium, and covered with an epoxy resin such that the indium surface was not exposed. This was then installed as the oxidation electrode 112.

In the oxidation-reduction reaction test, nitrogen gas was flowed at 10 ml/min in each reaction tank, the light irradiation area of the sample was set to 1 cm², and the aqueous solutions 111 and 121 were stirred at the center position of the bottom of each reaction tank at a rotational speed of 250 rpm using a stirring bar and stirrer.

After the inside of the reaction tanks was sufficiently replaced with nitrogen gas, the light source 140 was fixed such that it faced the surface where the p-type nickel oxide layer 14 (nickel oxide layer in Comparative Examples 1 and 2) was formed of the nitride semiconductor photoelectrode to be tested, which was installed as the oxidation electrode 112, and the nitride semiconductor photoelectrode was uniformly irradiated with light.

At an arbitrary time during the light irradiation, the gas in each reaction tank was collected and the reaction products were analyzed by gas chromatography. As a result, it was confirmed that oxygen was produced in the oxidation tank 110 and hydrogen in the reduction tank 120.

### Test Results

In the above-described oxidation-reduction reaction test, the amounts of oxygen and hydrogen produced 1 hour and 10 hours after the start of light irradiation are shown in the following Table 1. The amount of each gas produced was normalized by the surface area of the semiconductor photoelectrode. In all cases, it was found that oxygen and hydrogen were produced during the light irradiation.

TABLE 1

| | | | Amount of gas produced/ | | | |
|---|---|---|---|---|---|---|
| | | | μmol · cm⁻² · h⁻¹ | | | |
| | | Li | After | | After | |
| | Heat | compo- | 1 hour | | 10 hours | |
| | treatment | sition | Oxy- | Hydro- | Oxy- | Hydro- |
| Examples | temperature | ratio | gen | gen | gen | gen |
| Example 1 | 200° C. | 1% | 10.5 | 21.0 | 10.1 | 20.1 |
| Example 2 | 500° C. | 1% | 10.1 | 20.2 | 9.9 | 20.4 |
| Example 3 | 800° C. | 1% | 10.8 | 22.1 | 10.4 | 20.4 |
| Example 4 | 100° C. | 1% | 10.4 | 20.7 | 1.0 | 2.2 |
| Example 5 | 900° C. | 1% | 10.8 | 22.0 | 1.2 | 2.5 |
| Example 6 | 200° C. | 10% | 10.8 | 21.9 | 9.9 | 20.2 |
| Example 7 | 500° C. | 10% | 10.4 | 20.9 | 9.8 | 20.1 |
| Example 8 | 800° C. | 10% | 10.5 | 21.1 | 10.0 | 19.8 |
| Example 9 | 100° C. | 10% | 10.6 | 21.3 | 1.0 | 2.1 |
| Example 10 | 900° C. | 10% | 10.7 | 21.5 | 1.0 | 2.0 |
| Example 11 | 200° C. | 40% | 10.9 | 22.0 | 10.1 | 20.4 |
| Example 12 | 500° C. | 40% | 10.8 | 21.7 | 10.2 | 20.5 |
| Example 13 | 800° C. | 40% | 10.9 | 21.9 | 10.1 | 20.3 |
| Example 14 | 100° C. | 40% | 10.8 | 21.5 | 0.9 | 1.9 |
| Example 15 | 900° C. | 40% | 10.4 | 20.9 | 0.8 | 1.6 |
| Example 16 | — | 50% | — | — | — | — |
| Example 17 | 200° C. | 1% | 10.2 | 20.5 | 9.9 | 19.7 |
| Example 18 | 800° C. | 1% | 10.7 | 21.5 | 10.3 | 20.5 |
| Comparative | 200° C. | — | 1.3 | 2.5 | 1.1 | 2.1 |
| Example 1 | | | | | | |
| Comparative | 800° C. | — | 1.0 | 1.8 | 0.9 | 1.8 |
| Example 2 | | | | | | |

There was no significant difference observed in the amounts of hydrogen and oxygen produced 1 hour after the start of light irradiation in Examples 1 to 15, 17, and 18. Note that, in Example 16, where the composition ratio of lithium was set to 50%, no single phase of NiO was obtained, lithium oxide remained as an impurity, and the p-type nickel oxide layer 14 was not formed.

The amounts of hydrogen and oxygen produced 10 hours after the start of light irradiation in Examples 1, 2, 3, 6, 7, 8, 11, 12, 13, 17, and 18 were found to be 10 times higher than the amounts produced after 10 hours in the other Examples.

In Examples 4, 9, and 14, where the heat treatment temperature was set to 100° C., the amounts of hydrogen and oxygen produced 10 hours after the start of light irradiation were significantly decreased from the amounts produced 1 hour after the start of light irradiation. The aforementioned decrease is thought to be because the bonding between the p-type nickel oxide layer 14 and the indium gallium nitride layer 13 was weak in the case where the heat treatment temperature was 100° C. and voids were generated at the interface with the photocatalyst thin film, resulting in proceeding of degradation in electrode performance starting from the voids and approximately deactivation as a catalyst after 10 hours.

In Examples 5, 10, and 15, where the heat treatment temperature was set to 900° C., the amounts of hydrogen and oxygen produced 10 hours after the start of light irradiation were significantly decreased from the amounts produced 1 hour after the start of light irradiation. The aforementioned decrease is thought to be because the crystallinity of the indium gallium nitride layer 13 was poor in the case where the heat treatment temperature was 900° C., and the probability of recombination of the generated electrons and holes was increased due to the etching reaction proceeding along with the light irradiation, so that it became impossible to take out the charge necessary for the reaction 10 hours after the start of light irradiation.

From these results, it was extracted that the heat treatment condition of the fourth step, which is expected to extend the service life, is a temperature of 200° C. or higher and 800° C. or lower.

The amounts of oxygen and hydrogen produced 1 hour and 10 hours after the start of light irradiation in Examples 17 and 18 and those in Examples 1 and 3 were of the same level, indicating that forming the p-type nickel oxide layer 14 by sputtering had the same effect as forming the p-type nickel oxide layer 14 by vapor deposition.

In Comparative Examples 1 and 2, the amounts of hydrogen and oxygen produced were low at both 1 hour and 10 hours after the start of light irradiation. This is thought to be caused by, in the case of the nickel oxide layer, holes not being able to be transferred across the barrier at the interface with the indium gallium nitride layer.

From the above, in the method for producing a nitride semiconductor photoelectrode of the present embodiment, by setting the heat treatment conditions in the fourth step to 200° C. or higher and 800° C. or lower, and by setting the composition ratio of Li to Ni to 40% or less for fabricating the p-NiO powder used to form the p-type nickel oxide layer 14 in the third step, it became possible to increase the efficiency of the decomposition reaction of water (light energy conversion efficiency) and extend the service life.

As described above, the method for producing a nitride semiconductor photoelectrode of the present embodiment has: a first step of forming an n-type gallium nitride layer 12 on an electrically insulative or conductive substrate 11; a second step of forming an indium gallium nitride layer 13 on the n-type gallium nitride layer 12; a third step of forming a p-type nickel oxide layer 14 on the indium gallium nitride layer 13; and a fourth step of subjecting a nitride semiconductor in which the p-type nickel oxide layer 14 has been formed to heat treatment. In this manner, by forming a protective layer for oxygen generation that can maintain charge separation (generation and separation of electrons and holes) in the nitride semiconductor photoelectrode 1, holes generated in the indium gallium nitride layer 13 by light irradiation can be transferred to the p-type nickel oxide layer 14, and the nitride semiconductor photoelectrode 1 that can maintain the light energy conversion efficiency at a high level for a long time can be provided.

Note that, in the present embodiment, the target product is hydrogen, but by changing the reduction electrode 122 to, for example, Ni, Fe, Au, Pt, Ag, Cu, In, Ti, Co, or Ru, and by changing the atmosphere in the cell, it is also possible to produce carbon compounds through the reduction reaction of carbon dioxide or to produce ammonia through the reduction reaction of nitrogen.

### REFERENCE SIGNS LIST

1 Nitride semiconductor photoelectrode
11 Substrate
12 N-type gallium nitride layer
13 Indium gallium nitride layer
14 P-type nickel oxide layer

1. A method for producing a nitride semiconductor photoelectrode, the method comprising:
a first step of forming an n-type gallium nitride layer on an electrically insulative or conductive substrate;
a second step of forming an indium gallium nitride layer on the n-type gallium nitride layer;
a third step of forming a p-type nickel oxide layer on the indium gallium nitride layer; and
a fourth step of subjecting a nitride semiconductor in which the p-type nickel oxide layer has been formed to heat treatment.

2. The method for producing a nitride semiconductor photoelectrode according to claim 1, wherein metal organic chemical vapor deposition is used in the first step and the second step.

3. The method for producing a nitride semiconductor photoelectrode according to claim 1, wherein vapor deposition or sputtering is used in the third step.

4. The method for producing a nitride semiconductor photoelectrode according to claim 1, wherein the heat treatment is performed at a temperature of 200° C. or higher and 800° C. or lower in the fourth step.

5. The method for producing a nitride semiconductor photoelectrode according to claim 2, wherein vapor deposition or sputtering is used in the third step.

6. The method for producing a nitride semiconductor photoelectrode according to claim 2, wherein the heat treatment is performed at a temperature of 200° C. or higher and 800° C. or lower in the fourth step.

7. The method for producing a nitride semiconductor photoelectrode according to claim 3, wherein the heat treatment is performed at a temperature of 200° C. or higher and 800° C. or lower in the fourth step.
